(19) United States
(12) Patent Application Publication
(10) Pub. No.: US 2026/0239586 A1
(43) Pub. Date: Aug. 13, 2026

(54) ELECTRONIC ASSEMBLY INCLUDING A CONNECTING FORK

(71) Applicant: Valeo eAutomotive Germany GmbH, Erlangen (DE)

(72) Inventors: Romain HENNEGUET, Etaples-sur-Mer (FR); Vivek THANGARAJAN, Chennai (IN); Belber MARSHAL, Chennai (IN)

(73) Assignee: Valeo eAutomotive Germany GmbH, Erlangen (DE)

(21) Appl. No.: 19/536,824

(22) Filed: Feb. 11, 2026

(30) Foreign Application Priority Data
Feb. 11, 2025 (FR) FR2501427

(51) Int. Cl. H05K 7/20; H01R 12/58; H05K 7/10

(52) U.S. Cl. CPC H05K 7/20927; H01R 12/58; H05K 7/1061

(57) ABSTRACT

An electronic assembly including at least one power electronics module including at least one connection pin such as an angled connection pin, and a printed circuit board including electrical connection tracks and at least one electrical connection port. An intermediate electrical connector is placed between the power electronics module and the printed circuit board. The intermediate electrical connector includes at least one connecting fork arranged to be hot-crimped onto the connection pin of the power electronics module, and at least one intermediate pin, electrically connected to the connecting fork, and configured to be inserted into the at least one electrical connection port of the printed circuit board.

### FIELD OF THE INVENTION

The present invention relates to an electronic assembly including power electronics components, notably configured to be integrated in an inverter.

### Prior art

Patent application EP4362083A1 discloses an electronic assembly including power electronics modules interposed between two cooling devices arranged to cool the power electronics modules.

The power electronics modules include connection pins arranged to transmit signals to the power modules. These connection pins are therefore electrically connected to an intermediate connector force-fitted on an electronic board.

This connection method requires the connection pins of the power electronics modules to be soldered to the intermediate connector. This method represents an expensive assembly step, and requires precise relative positioning of the power electronics modules and the intermediate connector.

The invention aims notably to address these drawbacks.

### SUMMARY OF THE INVENTION

The invention relates to an electronic assembly including:
at least one power electronics module including at least one connection pin, notably an angled connection pin,
a printed circuit board including electrical connection tracks and at least one electrical connection port,
an intermediate electrical connector placed between the power electronics module and the printed circuit board, including:
   at least one connecting fork arranged to be hot-crimped onto the connection pin of the power electronics module,
   at least one intermediate pin, electrically connected to the connecting fork, and configured to be inserted into the at least one electrical connection port of the printed circuit board.

According to one aspect of the invention, the connecting fork is U-shaped, and includes two legs of length L spaced apart by a gap E.

According to one aspect of the invention, the gap E of the connecting fork enables the fork to be hot-crimped onto the angled connection pin with a tolerance in the relative placement of the fork and the connection pin greater than or equal to 1 mm.

Alternatively, the connecting fork may have any other shape, for example a circular or rectangular shape.

According to one aspect of the invention, the connecting fork may determine an open or closed contour.

According to one aspect of the invention, the connecting fork, the connection pin and the intermediate pin are made of electrically conductive materials, notably metal or metal alloy, optionally coated, notably with copper or copper alloy.

According to one aspect of the invention, the connecting fork, the intermediate pin and the connection pin are made of different copper alloys.

According to one aspect of the invention, the intermediate electrical connector includes a frame.

According to one aspect of the invention, the frame includes a plurality of positioning openings, notably as many positioning openings as there are power electronics modules, each positioning opening being arranged to accommodate a power electronics module.

According to one aspect of the invention, the electronic assembly includes a plurality of power electronics modules, for example three power electronics modules, and the intermediate electrical connector includes three positioning openings.

According to one aspect of the invention, the frame is made of insulating material, notably plastic.

According to one aspect of the invention, the connecting fork and the intermediate pin are permanently integrated in the frame.

According to one aspect of the invention, the frame is overmoulded on the intermediate pin and the connecting fork, integrating them inseparably.

According to one aspect of the invention, the intermediate pin has a press-fit geometry.

According to one aspect of the invention, the intermediate pin is electrically connected to an electrical track of the circuit board via a connection port of the printed circuit board by form-fitting and/or frictional locking and/or material locking.

Notably, the intermediate pin is electrically connected to an electrical track of the printed circuit board by interference fit, inserting the intermediate pin into the connection port of the printed circuit board.

According to one aspect of the invention, the power electronics module is substantially flat, and includes an upper face, a lower face and lateral surfaces.

According to one aspect of the invention, the electronic assembly includes at least one cooling device, placed in thermal contact with at least one power electronics module.

Notably, the electronic assembly includes two cooling devices:
a first cooling device placed in thermal contact with the upper face of the power electronics module,
a second cooling device placed in thermal contact with the second phase of the power electronics module.

According to one aspect of the invention, the intermediate electrical connector is interposed between the first cooling device and the second cooling device, and forms a stack with the first cooling device and the second cooling device.

According to one aspect of the invention, the connection pins of the power electronics modules are placed on lateral faces of the power electronics modules.

According to one aspect of the invention, each connection pin includes:
a horizontal portion substantially parallel to the upper face of the power electronics module,
a vertical portion, in a direction substantially normal to the upper face of the power electronics module,
an elbow connecting the horizontal portion and the vertical portion of the connection pin.

Advantageously, the use of angled connection pins on a lateral face of a power electronics module makes it possible to electrically connect the electronic board to the power electronics module when the upper and lower faces of the power electronics module are placed in contact with cooling devices.

According to one aspect of the invention, using angled connection pins enables the connection pins to be inserted into the connecting forks, enabling a solderless electrical connection to be made.

Advantageously, the use of connecting forks can increase the tolerances for the connection of the intermediate electrical connector to the angled connection pins of the power electronics modules.

According to one aspect of the invention, the use of greater tolerances ensures a more reliable assembly of the electronic assembly for mass production.

Advantageously, the use of hot crimping for the electrical connection can reduce costs and increase the reliability of these connections compared to a connection using a soldering process.

The invention also relates to a method for electrically interconnecting a power electronics module of an electronic assembly with a printed circuit board of this electronic assembly, comprising the following steps:
a step of placing at least one connection pin of the power electronics module opposite at least one connecting fork of an intermediate electrical connector,
a step of hot crimping the at least one connecting fork on the at least one connection pin,
a step of placing the printed circuit board opposite the intermediate electrical connector, such that the electrical connection ports of the printed circuit board are positioned opposite the intermediate pins of the printed circuit board,
a step of force-fitting the intermediate pins of the intermediate electrical connector into the connection ports of the printed circuit board.

According to one aspect of the invention, the hot-crimping step includes a step of heating the connecting fork, and a step of deforming the connecting fork, notably of deforming the legs of the connecting fork, so as to place the connecting fork in contact with the connection pin and secure the connecting fork and connection pin together.

### List of Figures

Other features, details and advantages of the invention will become more clearly apparent from reading the following description and from several examples of embodiments given by way of non-limiting indication with reference to the appended schematic drawings, in which:

FIG. 1 is a schematic view of an electronic assembly according to the invention.

FIG. 2 is a close-up view in cross section of an electronic assembly according to the invention.

FIG. 3 is a close-up top view of an electronic assembly according to the invention.

The features, variants and different embodiments of the invention may be combined with one another, in various combinations, provided that they are not mutually exclusive or incompatible. It will be possible, in particular, to imagine variants of the invention that comprise only a selection of features described below, in isolation from the other features described, provided that this selection of features is sufficient to confer a technical advantage and/or to distinguish the invention from the prior art.

### DETAILED DESCRIPTION

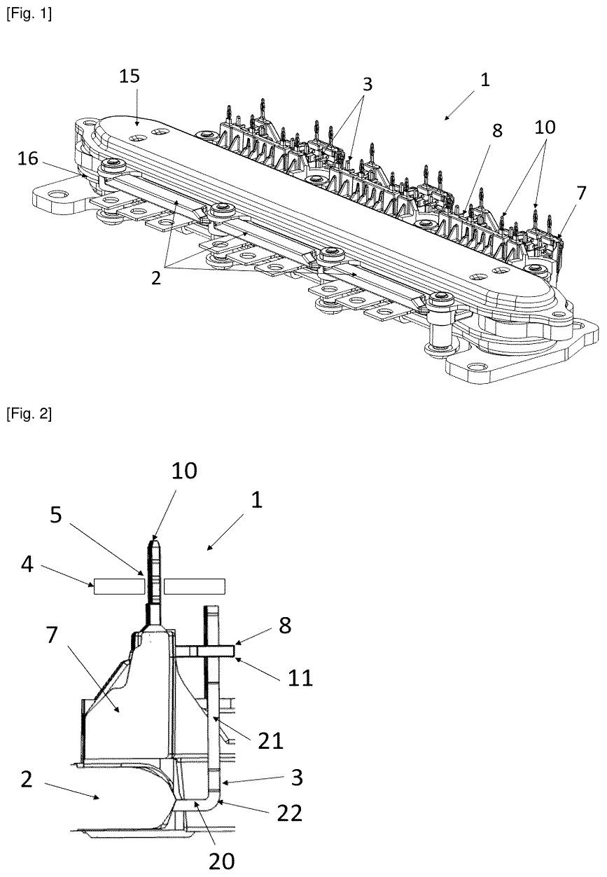

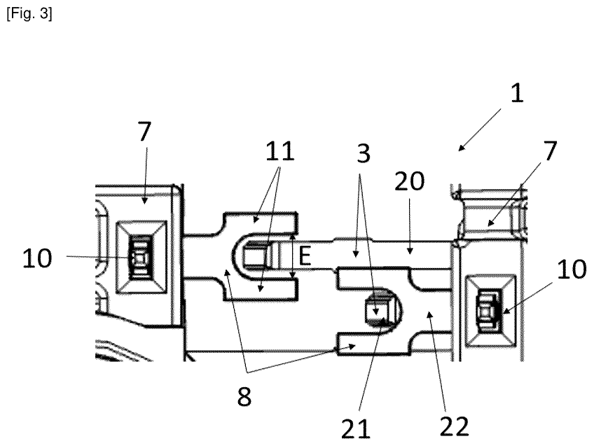

FIGS. 1 and 2 show an electronic assembly 1 according to the invention.

The electronic assembly 1 includes
three power electronics modules 2 each including at least one connection pin 3, notably an angled connection pin,
a printed circuit board 4, shown in FIG. 2 only, including electrical connection tracks and at least one electrical connection port 5,
an intermediate electrical connector 7 placed between the power electronics module 2 and the printed circuit board 4, including:
at least one connecting fork 8 arranged to be hot-crimped onto the connection pin 3 of the power electronics module 2,
at least one intermediate pin 10, electrically connected to the connecting fork 8, and configured to be inserted into the at least one electrical connection port 5 of the printed circuit board 4.

In this case, each power electronics module 2 includes seven angled connection pins 3, and the intermediate electrical connector 7 includes seven connecting forks 8 and seven intermediate pins 10.

The connecting forks 8 are U-shaped and include two legs 11 of length l spaced apart by a gap E.

The gap E of the connecting forks 8 enables the connecting forks 8 to be hot-crimped onto the angled connection pins 3 with a tolerance in the relative placement of the fork and the connection pin 3 greater than or equal to 1 mm.

According to an embodiment of the invention that is not shown, at least one connecting fork 8 may have any other shape, for example a circular or rectangular shape, and may determine an open or closed contour.

The connecting forks 8, the connection pins 3 and the intermediate pins 10 are made of electrically conductive materials, notably metal or metal alloy, optionally coated, notably with copper or copper alloy.

The connecting forks 8, the intermediate pins 10 and the connection pins 3 are made of different copper alloys, respectively.

The intermediate electrical connector 7 includes a frame 30 including a plurality of positioning openings, notably as many positioning openings as there are power electronics modules 2, each positioning opening being arranged to accommodate a power electronics module 2.

The electronic assembly 1 includes a plurality of power electronics modules 2, for example three power electronics modules 2, and the intermediate electrical connector 7 includes three positioning openings.

The connecting forks 8 and the intermediate pins 10 are permanently integrated in the frame 30.

The frame 30 is made of insulating material, notably plastic. and is overmoulded on the intermediate pins 10 and the connecting forks 8, integrating them inseparably.

The intermediate pins 10 have a press-fit geometry.

The intermediate pins 10 are electrically connected to an electrical track of the circuit board via a connection port of the printed circuit board 4 by form-fitting and/or frictional locking and/or material locking.

Notably, the intermediate pins 10 are electrically connected to an electrical track of the printed circuit board 4 by interference fit, inserting the intermediate pins 10 into the electrical connection port 5 of the printed circuit board 4.

The power electronics module 2 is substantially flat, and includes an upper face, a lower face and lateral surfaces.

The electronic assembly 1 includes at least one cooling device, placed in thermal contact with at least one power electronics module 2.

In this case, the electronic assembly 1 includes two cooling devices:
a first cooling device 15 placed in thermal contact with the upper face of the power electronics module 2,
a second cooling device 16 placed in thermal contact with the second phase of the power electronics module 2.

The intermediate electrical connector 7 is interposed between the first cooling device 15 and the second cooling device 16, and forms a stack with the first cooling device 15 and the second cooling device 16.

The connection pins 3 of the power electronics modules 2 are placed on lateral faces of the power electronics modules 2.

Each connection pin 3 includes:
a horizontal portion 20 substantially parallel to the upper face of the power electronics module 2,
a vertical portion 21, in a direction substantially normal to the upper face of the power electronics module 2,
an elbow 22 connecting the horizontal portion and the vertical portion of the connection pin 3.

By using angled connection pins 3, the connection pins 3 can be inserted into the connecting forks 8 and a solderless electrical connection can be made.

Advantageously, the use of connecting forks 8 can increase the tolerances for the connection of the intermediate electrical connector 7 to the angled connection pins 3 of the power electronics modules 2.

The use of greater tolerances ensures a more reliable assembly of the electronic assembly 1 for mass production.

Advantageously, the use of hot crimping for the electrical connection can reduce costs and increase the reliability of these connections compared to a connection using a soldering process.

1. Electronic assembly including:
at least one power electronics module including at least one connection pin, notably an angled connection pin,
a printed circuit board including electrical connection tracks and at least one electrical connection port,
an intermediate electrical connector placed between the power electronics module and the printed circuit board, including:
at least one connecting fork arranged to be hot-crimped onto the connection pin of the power electronics module,
at least one intermediate pin, electrically connected to the connecting fork, and configured to be inserted into the at least one electrical connection port of the printed circuit board.

2. Electronic assembly according to claim 1, wherein the connecting fork is U-shaped, and includes two legs of length L spaced apart by a gap E, this gap E of the connecting fork enabling the fork to be hot-crimped onto the angled connection pin with a tolerance in the relative placement of the fork and the connection pin greater than or equal to 1 mm.

3. Electronic assembly according to claim 1, wherein the connecting fork, the intermediate pin and the connection pin are made of different copper alloys.

4. Electronic assembly according to claim 1, wherein the intermediate electrical connector includes a frame made of insulating material, notably plastic, and the connecting fork and the intermediate pin are permanently integrated in the frame.

5. Electronic assembly according to claim 1, wherein the intermediate pin has a press-fit geometry.

6. Electronic assembly according to claim 1, wherein the intermediate pin is electrically connected to an electrical track of the circuit board via a connection port of the printed circuit board by form-fitting and/or frictional locking and/or material locking.

7. Electronic assembly according to claim 1, including at least one cooling device, placed in thermal contact with at least one power electronics module.

8. Electronic assembly according to claim 1, wherein the connection pins of the power electronics modules are placed on lateral faces of the power electronics modules.

9. Electronic assembly according to claim 1, wherein each connection pin includes:
a horizontal portion substantially parallel to the upper face of the power electronics module,
a vertical portion, in a direction substantially normal to the upper face of the power electronics module,
an elbow connecting the horizontal portion and the vertical portion of the connection pin.

10. Method of electrically interconnecting a power electronics module of an electronic assembly according to claim 1 with a printed circuit board of said electronic assembly, comprising the following steps:
a step of placing at least one connection pin of the power electronics module opposite at least one connecting fork of an intermediate electrical connector,
a step of hot crimping the at least one connecting fork on the at least one connection pin,
a step of placing the printed circuit board opposite the intermediate electrical connector, such that the electrical connection ports of the printed circuit board are positioned opposite the intermediate pins of the printed circuit board,
a step of force-fitting the intermediate pins of the intermediate electrical connector into the connection ports of the printed circuit board.

11. Method according to claim 10, wherein the hot-crimping step includes a step of heating the connecting fork, and a step of deforming the connecting fork, notably of deforming the legs of the connecting fork, so as to place the connecting fork in contact with the connection pin and secure the connecting fork and connection pin together.

12. Electronic assembly according to claim 2, wherein the connecting fork, the intermediate pin and the connection pin are made of different copper alloys.

13. Electronic assembly according to claim 2, wherein the intermediate electrical connector includes a frame made of insulating material, notably plastic, and the connecting fork and the intermediate pin are permanently integrated in the frame.

14. Electronic assembly according to claim 2, wherein the intermediate pin has a press-fit geometry.

15. Electronic assembly according to claim 2, wherein the intermediate pin is electrically connected to an electrical track of the circuit board via a connection port of the printed circuit board by form-fitting and/or frictional locking and/or material locking.

16. Electronic assembly according to claim 2, including at least one cooling device, placed in thermal contact with at least one power electronics module.

17. Electronic assembly according to claim 2, wherein the connection pins of the power electronics modules are placed on lateral faces of the power electronics modules.

18. Electronic assembly according to claim 2, wherein each connection pin includes:
a horizontal portion substantially parallel to the upper face of the power electronics module,
a vertical portion, in a direction substantially normal to the upper face of the power electronics module,
an elbow connecting the horizontal portion and the vertical portion of the connection pin.

19. Method of electrically interconnecting a power electronics module of an electronic assembly according to claim 2 with a printed circuit board of said electronic assembly, comprising the following steps:
a step of placing at least one connection pin of the power electronics module opposite at least one connecting fork of an intermediate electrical connector,
a step of hot crimping the at least one connecting fork on the at least one connection pin,
a step of placing the printed circuit board opposite the intermediate electrical connector, such that the electrical connection ports of the printed circuit board are positioned opposite the intermediate pins of the printed circuit board,
a step of force-fitting the intermediate pins of the intermediate electrical connector into the connection ports of the printed circuit board.

20. Electronic assembly according to claim 3, wherein the intermediate electrical connector includes a frame made of insulating material, notably plastic, and the connecting fork and the intermediate pin are permanently integrated in the frame.
